(19) United States
(12) Patent Application Publication
(10) Pub. No.: US 2025/0300630 A1
(43) Pub. Date: Sep. 25, 2025

(54) ACOUSTIC WAVE DEVICE WITH CONDUCTIVE STRUCTURE

(71) Applicant: Skyworks Solutions, Inc., Irvine, CA (US)

(72) Inventor: Rei Goto, Osaka-Shi (JP)

(21) Appl. No.: 19/069,673

(22) Filed: Mar. 4, 2025

Related U.S. Application Data
(60) Provisional application No. 63/567,086, filed on Mar. 19, 2024.
(60) Provisional application No. 63/567,090, filed on Mar. 19, 2024.
(60) Provisional application No. 63/567,176, filed on Mar. 19, 2024.
(60) Provisional application No. 63/567,097, filed on Mar. 19, 2024.

(51) Int. Cl. H03H 9/25; H03H 9/02; H03H 9/64

(52) U.S. Cl. CPC H03H 9/25; H03H 9/02834; H03H 9/02992; H03H 9/6483

(57) ABSTRACT

An acoustic wave device is disclosed. The acoustic wave device can include a piezoelectric layer, an interdigital transducer electrode over the piezoelectric layer, and a conductive structure. The interdigital transducer electrode includes a first bus bar, a first set of fingers extending from the first bus bar, a second bus bar, and a second set of fingers extending from the second bus bar. The conductive structure can include a first portion positioned on the first bus bar and a second portion at least partially positioned over the first set of finger fingers. The second portion is spaced from the first set of fingers by a gap.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/567,086, filed Mar. 19, 2024, titled “ACOUSTIC WAVE SYSTEM WITH CONDUCTIVE STRUCTURE,” U.S. Provisional Patent Application No. 63/567,090, filed Mar. 19, 2024, titled “MULTI-MODE SURFACE ACOUSTIC WAVE DEVICE WITH CONDUCTIVE STRUCTURE,” U.S. Provisional Patent Application No. 63/567,176, filed Mar. 19, 2024, titled “METHOD OF FORMING AN ELECTRICAL CONNECTION COUPLED TO A RESONATOR,” and U.S. Provisional Patent Application No. 63/567,097, filed Mar. 19, 2024, titled “ACOUSTIC WAVE DEVICE WITH CONDUCTIVE STRUCTURE,” are hereby incorporated by reference under 37 CFR 1.57 in their entirety.

### BACKGROUND

### Field

Embodiments of this disclosure relate to multilayer piezoelectric substrate surface acoustic wave (MPS SAW) devices.

### Description of Related Technology

Acoustic wave filters can be implemented in radio frequency electronic apparatuses. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an acoustic wave system including: a first resonator including an interdigital transducer electrode having a first bus bar, a first finger extending from the first bus bar, a second bus bar, and a second finger extending from the second bus bar; a second resonator; and a conductive structure including a first portion extending between the first resonator and the second resonator, and a second portion at least partially positioned over the first finger, the second portion spaced from the first finger.

In some embodiments, the techniques described herein relate to an acoustic wave system wherein the second portion is spaced from the first finger at least by an air gap.

In some embodiments, the techniques described herein relate to an acoustic wave system wherein the interdigital transducer electrode includes a first gap region between the first bus bar and the second finger, a second gap region between the second bus bar and the first finger, and an active region between the first gap region and the second gap region, the second portion is at least partially positioned over the active region.

In some embodiments, the techniques described herein relate to an acoustic wave system wherein the first portion of the conductive structure at least partially positioned on the first bus bar.

In some embodiments, the techniques described herein relate to an acoustic wave system wherein the first resonator and the second resonator are spaced apart by a distance in a range between 1 micrometer and 20 micrometers.

In some embodiments, the techniques described herein relate to an acoustic wave system wherein the conductive structure includes aluminum.

In some embodiments, the techniques described herein relate to an acoustic wave system wherein the first resonator includes a ladder filter.

In some embodiments, the techniques described herein relate to an acoustic wave system further including a third resonator electrically coupled to the first resonator through the conductive structure.

In some embodiments, the techniques described herein relate to an acoustic wave system further including a piezoelectric layer, wherein the first resonator and the second resonator are positioned on the piezoelectric layer.

In some embodiments, the techniques described herein relate to an acoustic wave system wherein the first resonator further includes a first reflector and a second reflector, the interdigital transducer electrode is positioned between the first and second reflectors.

In some embodiments, the techniques described herein relate to an acoustic wave system wherein the first resonator is a temperature compensated surface acoustic wave resonator or a multi-layer piezoelectric substrate surface acoustic wave resonator.

In some aspects, the techniques described herein relate to an acoustic wave system including: an interdigital transducer electrode including a bus bar and a finger extending from the bus bar; a terminal; and a conductive structure including a first portion at least partially positioned over the bus bar and a second portion at least partially positioned over the finger, the second portion spaced from the finger, the interdigital transducer electrode and the terminal electrically coupled by the conductive structure.

In some embodiments, the techniques described herein relate to an acoustic wave system wherein the second portion is spaced from the finger at least by an air gap.

In some embodiments, the techniques described herein relate to an acoustic wave system wherein the first portion extends between the bus bar and the terminal.

In some embodiments, the techniques described herein relate to an acoustic wave system further including a piezoelectric layer, wherein the interdigital transducer electrode and terminal are positioned on the piezoelectric layer.

In some embodiments, the techniques described herein relate to an acoustic wave system further including a second interdigital transducer electrode including the terminal.

In some embodiments, the techniques described herein relate to an acoustic wave system wherein the terminal is configured to connect to an external substrate or another system.

In some embodiments, the techniques described herein relate to an acoustic wave system wherein the interdigital transducer electrode further includes a second bus bar and a second finger extending from the second bus bar, the interdigital transducer electrode includes a first gap region between the bus bar and the second finger, a second gap region between the second bus bar and the finger, and an active region between the first gap region and the second gap region, the second portion is at least partially positioned over the active region.

In some aspects, the techniques described herein relate to an acoustic wave system including: a first interdigital transducer electrode including a first bus bar, a first set of fingers extending from the first bus bar, a second bus bar, and a second set of fingers extending from the second bus bar; a second interdigital transducer electrode; and a conductive structure including a first portion extending between the first and second interdigital transducer electrodes, and a second portion positioned at least partially over a gap region between the first bus bar and the second set of fingers.

In some embodiments, the techniques described herein relate to an acoustic wave system wherein the second portion and the first set of fingers are spaced apart at least by an air gap.

In some aspects, the techniques described herein relate to a multi-mode surface acoustic wave device including: a first interdigital transducer electrode; a second interdigital transducer electrode longitudinally positioned from the first interdigital transducer electrode; and a conductive structure connecting the first interdigital transducer electrode and the second interdigital transducer electrode, the conductive structure including a first portion connected to a bus bar of the first interdigital transducer electrode and a second portion positioned at least partially over an active region of the first interdigital transducer electrode, the second portion spaced from the active region of the first interdigital transducer electrode by a gap.

In some embodiments, the techniques described herein relate to a multi-mode surface acoustic wave device wherein the second portion is spaced from the active region of the first interdigital transducer electrode by an air gap.

In some embodiments, the techniques described herein relate to a multi-mode surface acoustic wave device wherein conductive structure is connected to ground.

In some embodiments, the techniques described herein relate to a multi-mode surface acoustic wave device further including a second conductive structure electrically connecting the first and second interdigital transducer electrodes, wherein the second conductive structure connected to a signal line.

In some embodiments, the techniques described herein relate to a multi-mode surface acoustic wave device wherein the conductive structure includes aluminum.

In some embodiments, the techniques described herein relate to a multi-mode surface acoustic wave device further including a third interdigital transducer electrode electrically coupled to the first interdigital transducer electrode through the conductive structure.

In some embodiments, the techniques described herein relate to a multi-mode surface acoustic wave device further including a piezoelectric layer, wherein the first interdigital transducer electrode and the second interdigital transducer electrode are positioned on the piezoelectric layer.

In some embodiments, the techniques described herein relate to a multi-mode surface acoustic wave device further including a first reflector and a second reflector, the first and second interdigital transducer electrodes are positioned between the first and second reflectors.

In some aspects, the techniques described herein relate to a multi-mode surface acoustic wave device including: a first interdigital transducer electrode including a first bus bar and a first finger extending from the first bus bar; a second interdigital transducer including a second bus bar and a second finger extending from the second bus bar; and a conductive structure including a first portion positioned on the first bus bar, a second portion at least partially positioned over the first finger, and a third portion positioned on the second bus bar, the second portion extends between the first and third portions and spaced from the first finger by a gap.

In some embodiments, the techniques described herein relate to a multi-mode surface acoustic wave device wherein the second portion is at least partially positioned over the second finger.

In some embodiments, the techniques described herein relate to a multi-mode surface acoustic wave device wherein the second portion is spaced from the first finger by an air gap.

In some embodiments, the techniques described herein relate to a multi-mode surface acoustic wave device wherein conductive structure is connected to ground.

In some embodiments, the techniques described herein relate to a multi-mode surface acoustic wave device further including a second conductive structure electrically connecting the first and second interdigital transducer electrodes, wherein the second conductive structure connected to a signal line.

In some embodiments, the techniques described herein relate to a multi-mode surface acoustic wave device wherein the conductive structure includes aluminum.

In some embodiments, the techniques described herein relate to a multi-mode surface acoustic wave device further including a third interdigital transducer electrode electrically coupled to the first interdigital transducer electrode through the conductive structure.

In some embodiments, the techniques described herein relate to a multi-mode surface acoustic wave device further including a piezoelectric layer, wherein the first interdigital transducer electrode and the second interdigital transducer electrode are positioned on the piezoelectric layer.

In some embodiments, the techniques described herein relate to a multi-mode surface acoustic wave device further including a first reflector and a second reflector, the first and second interdigital transducer electrodes are positioned between the first and second reflectors.

In some aspects, the techniques described herein relate to a multi-mode surface acoustic wave device including: a first interdigital transducer electrode including an active region; a second interdigital transducer electrode longitudinally positioned from the first interdigital transducer electrode; and a conductive structure electrically connecting the first and second interdigital transducer electrodes, at least a portion of the conductive structure being positioned over and spaced apart from the active region of the first interdigital transducer electrode.

In some embodiments, the techniques described herein relate to a multi-mode surface acoustic wave device wherein the portion of the conductive structure is spaced apart from the active region by an air gap.

In some embodiments, the techniques described herein relate to a multi-mode surface acoustic wave device further including a third interdigital transducer electrode electrically coupled to the first interdigital transducer electrode through the conductive structure.

In some aspects, the techniques described herein relate to a method of forming an acoustic wave system including a resonator, the method including: providing a patterned sacrificial layer over an active region of the resonator; forming a conductive structure including a first portion on a bus bar of the resonator and a second portion at least partially over the patterned sacrificial layer; and removing the patterned sacrificial layer.

In some embodiments, the techniques described herein relate to a method wherein providing the patterned sacrificial layer includes depositing a sacrificial material over the resonator and removing portions of the sacrificial material to form the patterned sacrificial layer over the active region of the resonator.

In some embodiments, the techniques described herein relate to a method wherein forming the conductive structure includes providing a conductive layer over the patterned sacrificial layer and removing at least a portion of the conductive layer to leave the second portion over a portion of the patterned sacrificial layer.

In some embodiments, the techniques described herein relate to a method wherein the conductive structure further includes a third portion electrically connected to a second resonator.

In some embodiments, the techniques described herein relate to a method wherein the resonator and the second resonator are spaced apart by a distance in a range between 1 micrometer and 20 micrometers.

In some embodiments, the techniques described herein relate to a method wherein forming the conductive structure includes providing depositing aluminum.

In some embodiments, the techniques described herein relate to a method further including forming the resonator on a piezoelectric layer.

In some aspects, the techniques described herein relate to a method of forming an acoustic wave system including an interdigital transducer electrode, the method including: providing a patterned sacrificial layer over an active region of the interdigital transducer electrode; forming a conductive structure including a first portion on a bus bar of the interdigital transducer electrode and a second portion at least partially over the patterned sacrificial layer; and removing the patterned sacrificial layer.

In some embodiments, the techniques described herein relate to a method wherein providing the patterned sacrificial layer includes depositing a sacrificial material over the interdigital transducer electrode and removing portions of the sacrificial material to form the patterned sacrificial layer over the active region of the interdigital transducer electrode.

In some embodiments, the techniques described herein relate to a method wherein forming the conductive structure includes providing a conductive layer over the patterned sacrificial layer and removing at least a portion of the conductive layer to leave the second portion over a portion of the patterned sacrificial layer.

In some embodiments, the techniques described herein relate to a method wherein the conductive structure further includes a third portion electrically connected to a second interdigital transducer electrode.

In some embodiments, the techniques described herein relate to a method wherein the interdigital transducer electrode and the second interdigital transducer electrode are spaced apart by a distance in a range between 1 micrometer and 20 micrometers.

In some embodiments, the techniques described herein relate to a method wherein the interdigital transducer electrode and the second interdigital transducer electrode are acoustically coupled longitudinally.

In some embodiments, the techniques described herein relate to a method wherein forming the conductive structure includes providing depositing aluminum.

In some embodiments, the techniques described herein relate to a method further including forming the interdigital transducer electrode on a piezoelectric layer.

In some aspects, the techniques described herein relate to a method of forming an acoustic wave system, the method including: providing an interdigital transducer electrode including a first bus bar, a first set of fingers extending from the first bus bar, a second bus bar, and a second set of fingers extending from the second bus bar; providing a patterned sacrificial layer over the first and second sets of fingers; forming a conductive structure including a first portion on the first bus bar of the interdigital transducer electrode and a second portion at least partially over the patterned sacrificial layer; and removing the patterned sacrificial layer.

In some aspects, the techniques described herein relate to a method wherein the interdigital transducer electrode includes a first gap region between the first bus bar and the second set of fingers, a second gap region between the second bus bar and the first set of fingers, and an active region between the first and second gap regions, the second portion is at least partially positioned over the active region.

In some embodiments, the techniques described herein relate to a method wherein the second portion and the active region are spaced apart by an air gap.

In some embodiments, the techniques described herein relate to a method further including providing a second interdigital transducer electrode, wherein forming the conductive structure includes providing an electrical connection between the first and second interdigital transducer electrodes.

In some embodiments, the techniques described herein relate to a method wherein the interdigital transducer electrode and the second interdigital transducer electrode are spaced apart by a distance in a range between 1 micrometer and 20 micrometers.

In some aspects, the techniques described herein relate to an acoustic wave device including: a piezoelectric layer; an interdigital transducer electrode over the piezoelectric layer, the interdigital transducer electrode including a first bus bar, a first set of fingers extending from the first bus bar, a second bus bar, and a second set of fingers extending from the second bus bar; and a conductive structure including a first portion positioned on the first bus bar and a second portion at least partially positioned over the first set of finger fingers, the second portion spaced from the first set of fingers by a gap.

In some embodiments, the techniques described herein relate to an acoustic wave device wherein the gap is an air gap.

In some embodiments, the techniques described herein relate to an acoustic wave device further including a temperature compensation layer between the air gap and the interdigital transducer electrode.

In some aspects, the techniques described herein relate to an acoustic wave device wherein the interdigital transducer electrode includes a first gap region between the first bus bar and the second set of fingers, a second gap region between the second bus bar and the first set of fingers, and an active region between the first and second gap regions, the second portion is at least partially positioned over the first gap region.

In some embodiments, the techniques described herein relate to an acoustic wave device wherein the second portion is at least partially positioned over the active region.

In some embodiments, the techniques described herein relate to an acoustic wave device further including a second conductive structure, wherein the second conductive structure includes a third portion positioned on the second bus bar and a fourth portion at least partially positioned over the second gap region, the second portion is spaced from the second set of fingers.

In some embodiments, the techniques described herein relate to an acoustic wave device wherein the fourth portion is at least partially positioned over the active region.

In some embodiments, the techniques described herein relate to an acoustic wave device further including a first reflector and a second reflector, the interdigital transducer electrode positioned between the first and second reflectors.

In some embodiments, the techniques described herein relate to an acoustic wave device wherein the second portion is at least partially positioned over the first reflector.

In some embodiments, the techniques described herein relate to an acoustic wave device wherein the piezoelectric layer includes lithium niobate or lithium tantalate.

In some embodiments, the techniques described herein relate to an acoustic wave device further including a support substrate, the piezoelectric layer is positioned between the support substrate and the interdigital transducer electrode.

In some aspects, the techniques described herein relate to an acoustic wave device including: a piezoelectric layer; an interdigital transducer electrode over the piezoelectric layer, the interdigital transducer electrode including a first gap region, a second gap region, and an active region laterally between the first and second gap regions; and a conductive structure electrically connected to the interdigital transducer electrode, a portion of the conductive structure positioned over the first gap region, the portion of the conductive structure spaced from the first gap region by an air gap.

In some embodiments, the techniques described herein relate to an acoustic wave device wherein the portion of the conductive structure is positioned over the active region.

In some embodiments, the techniques described herein relate to an acoustic wave device further including a second conductive structure, wherein the second conductive structure is at least partially positioned over the active region.

In some embodiments, the techniques described herein relate to an acoustic wave device wherein the conductive structure includes a first metal layer and a second metal layer over the first layer.

In some embodiments, the techniques described herein relate to an acoustic wave device wherein the first layer and the second metal layer include different materials.

In some embodiments, the techniques described herein relate to an acoustic wave device wherein the second layer is thicker than the first layer.

In some embodiments, the techniques described herein relate to an acoustic wave system including the acoustic wave device and another acoustic wave device.

In some aspects, the techniques described herein relate to a surface acoustic wave device including: a piezoelectric layer; an interdigital transducer electrode over the piezoelectric layer; and a conductive structure electrically connected to a terminal of the interdigital transducer electrode and partially positioned over an active region of the interdigital transducer electrode, the conductive structure spaced from the interdigital transducer electrode by an air gap.

In some embodiments, the techniques described herein relate to an acoustic wave system including the acoustic wave device and a second acoustic wave device spaced from the acoustic wave device by a distance in a range between 1 micrometer and 20 micrometers.

The present disclosure relates to U.S. Patent Application No. ______, titled “ACOUSTIC WAVE SYSTEM WITH CONDUCTIVE STRUCTURE,” U.S. Patent Application No. ______, titled “MULTI-MODE SURFACE ACOUSTIC WAVE DEVICE WITH CONDUCTIVE STRUCTURE,” and U.S. Patent Application No. ______, titled “METHOD OF FORMING AN ELECTRICAL CONNECTION COUPLED TO A RESONATOR,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic top plan view of an acoustic wave system.

FIG. 1B is a schematic cross-sectional side view of the acoustic wave system of FIG. 1A.

FIG. 2A is a schematic top plan view of an acoustic wave system according to an embodiment.

FIG. 2B is a schematic cross-sectional side view of the acoustic wave system of FIG. 2A.

FIG. 3 is a schematic cross-sectional side view of another acoustic wave system.

FIG. 4 is a graph of simulation results showing filter performance of the acoustic wave systems of FIGS. 1A-3.

FIG. 5A is a schematic cross-sectional side view of a portion of the acoustic wave device of FIG. 1A showing displacement in the acoustic wave device.

FIG. 5B is a schematic perspective view of the acoustic wave device of FIG. 5A.

FIG. 6A is a schematic cross-sectional side view of a portion of the acoustic wave device of FIG. 2A showing displacement in the acoustic wave device.

FIG. 6B is a schematic perspective view of the acoustic wave device of FIG. 6A.

FIG. 7A is a schematic cross-sectional side view of a portion of the acoustic wave device of FIG. 3 showing displacement in the acoustic wave device.

FIG. 7B is a schematic perspective view of the acoustic wave device of FIG. 7A.

FIGS. 8A-8C are graphs showing simulated admittance of the acoustic wave systems of FIGS. 1A-3.

FIG. 9A is a schematic cross-sectional side view of an acoustic wave device according to an embodiment.

FIG. 9B is a schematic top plan view of the acoustic wave device of FIG. 9A.

FIGS. 10A-10H show an example method of forming the acoustic wave device of FIG. 9A according to an embodiment.

FIG. 11A is a schematic top plan view of a multi-mode surface acoustic wave device according to an embodiment.

FIG. 11B is a schematic cross-sectional side view of the multi-mode surface acoustic wave device of FIG. 11A.

FIG. 11C is a schematic top plan view of a multi-mode surface acoustic wave device according to another embodiment.

FIG. 12A is a schematic cross-sectional side view of an acoustic wave device according to an embodiment.

FIG. 12B is a schematic cross-sectional side view of an acoustic wave device according to another embodiment.

FIG. 13A is a schematic diagram of a transmit filter that includes a surface acoustic wave resonator according to an embodiment.

FIG. 13B is a schematic diagram of a receive filter that includes a surface acoustic wave resonator according to an embodiment.

FIG. 14 is a schematic diagram of a radio frequency module that includes a surface acoustic wave resonator according to an embodiment.

FIG. 15 is a schematic diagram of a radio frequency module that includes filters with surface acoustic wave resonators according to an embodiment.

FIG. 16 is a schematic block diagram of a module that includes an antenna switch and duplexers that include a surface acoustic wave resonator according to an embodiment.

FIG. 17A is a schematic block diagram of a module that includes a power amplifier, a radio frequency switch, and duplexers that include a surface acoustic wave resonator according to an embodiment.

FIG. 17B is a schematic block diagram of a module that includes filters, a radio frequency switch, and a low noise amplifier according to an embodiment.

FIG. 18A is a schematic block diagram of a wireless communication device that includes a filter with a surface acoustic wave resonator in accordance with one or more embodiments.

FIG. 18B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Various features discussed herein can be implemented in any suitable SAW device such as a temperature compensated (TC) SAW device and a multilayer piezoelectric substrate (MPS) SAW device.

A plurality of acoustic wave resonators (e.g., SAW resonators) can be included in an acoustic wave system. Two or more of the resonators can be electrically coupled to one another through an electrical connection. The electrical connection can include a metal layer or trace that extends between a terminal of a resonator to another terminal of another resonator. In modern-day technology, miniaturization of the RF device is critical, and the lateral size added by the spacings or gaps between the resonators can be undesirable. It can be challenging to minimize the gap between the resonators because when the gap is significantly small, there can be, for example, resistive losses in the electrical connection between the resonators which can contribute to creating insertion losses.

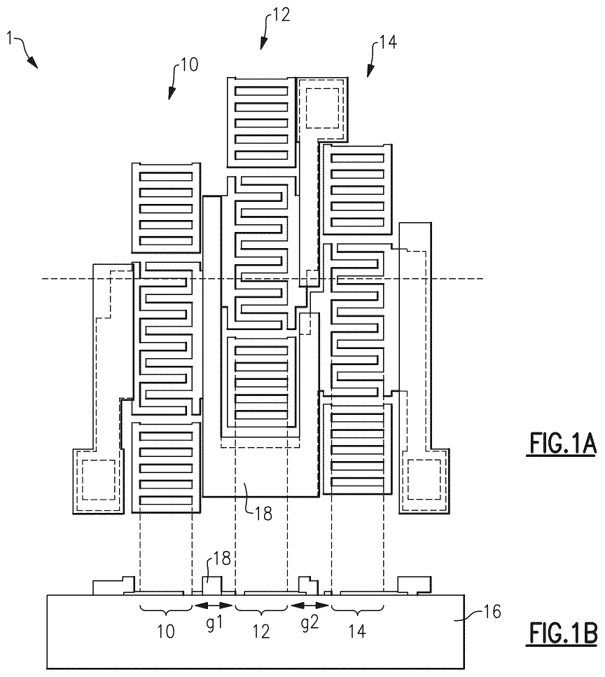

One approach to reduce the resistive loss in the electrical connection between the resonators is to have a thicker metal in the gap. FIG. 1A is a schematic top plan view of an acoustic wave system 1 that includes a first filter 10, a second filter 12, and a third filter 14. FIG. 1B is a schematic cross-sectional side view of the acoustic wave system 1 of FIG. 1A. The first filter 10, a second filter 12, and the third filter 14 are closely positioned on a piezoelectric layer 16. A gap g1 between the first filter 10 and the second filter 12 and a gap g2 between the second filter 12 and the third filter 14 can limit the width of the metal layer 18 that connects the first filter 10, a second filter 12, and a third filter 14. In the acoustic wave system 1, the thickness of the metal layer 18 is increased to reduce the resistive losses. However, when the gap is significantly small, even with the thicker metal, there can be significant losses.

Various embodiments disclosed herein relate to structures and methods of manufacturing the structures that can reduce losses in an electrical connection between two or more acoustic wave components. In some embodiments, an acoustic wave system, such as a filter system, can include two or more acoustic wave devices. The acoustic wave devices can include surface acoustic wave (SAW) devices (e.g., SAW resonators). For example, the SAW devices can include a ladder filter. Two or more interdigital transducer electrodes of the resonators in the acoustic wave system can be connected through the electrical connection. In some embodiments, the acoustic wave system can include a multi-mode surface acoustic wave (MMS) device, such as a double-mode surface acoustic wave (DMS) device, that includes two or more interdigital transducer electrodes that are positioned in the longitudinal direction (e.g., a wave propagation direction), acoustically coupled longitudinally, and electrically connected through the electrical connection. A conductive structure can include the electrical connection. The conductive structure can include a first portion that is electrically connected to a terminal of an interdigital transducer electrode and a second portion that is positioned over a set of fingers of the interdigital transducer electrode. The terminal can be provided with a bus bar of the interdigital transducer electrode and the set of fingers extend from the bus bar. The second portion is spaced apart from the fingers by a gas gap (e.g., an air gap). In some embodiments, the second portion can overlap the active region of the interdigital transducer electrode.

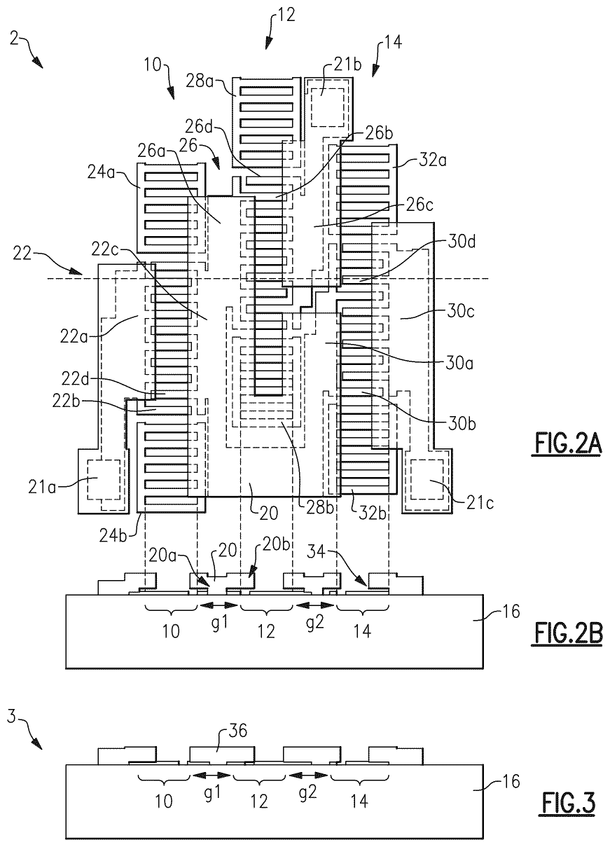

FIG. 2A is a schematic top plan view of an acoustic wave system 2 according to an embodiment. FIG. 2B is a schematic cross-sectional side view of the acoustic wave system 2 of FIG. 2A. The acoustic wave system 2 can include a plurality of acoustic wave devices. In FIGS. 2A and 2B, a first filter 10, a second filter 12, and a third filter 14 are illustrated as examples of the acoustic wave devices. Each of the first to third filters 10, 12, 14 can include an interdigital transducer electrode positioned between a pair of reflectors. Although the first to third filter 10, 12, 14 (e.g., the ladder filters) are illustrated as an example, any suitable principles and advantages disclosed herein can be implemented with any suitable acoustic wave devices (e.g., a surface acoustic wave (SAW) resonator). The acoustic wave system 2 can also include a conductive structure 20 and terminals 21a, 21b, 21c. The terminals 21a, 21b, 21c can be configured to connect to an external substrate or a larger system. The terminals 21a, 21b, 21c can include a contact pad, in some embodiments.

The first filter 10 can include an interdigital transducer electrode 22 and a pair of reflectors 24a, 24b. The interdigital transducer electrode 22 includes a bus bar 22a, fingers 22b that extend from the bus bar 22a, a bus bar 22c, and fingers 22d that extend from the bus bar 22c. Similarly, the second filter 12 can include an interdigital transducer electrode 26 and a pair of reflectors 28a, 28b, and the third filter 14 can include an interdigital transducer electrode 30 and a pair of reflectors 32a, 32b. The interdigital transducer electrode 26 includes a bus bar 26a, fingers 26b that extend from the bus bar 26a, a bus bar 26c, and fingers 26d that extend from the bus bar 26c. The interdigital transducer electrode 30 includes a bus bar 30a, fingers 30b that extend from the bus bar 30a, a bus bar 30c, and fingers 30d that extend from the bus bar 30c.

The interdigital transducer electrode 22 can include a gap region between the fingers 22b and the bus bar 22c, a gap region between the fingers 22d and the first bus bar 22a, and an active region between the gap regions. In the active region, the fingers 22b and the fingers 22d can overlap in the longitudinal direction (e.g., the wave propagation direction). Similarly, the interdigital transducer electrode 26 can include a gap region between the fingers 26b and the bus bar 26c, a gap region between the fingers 26d and the first bus bar 26a, and an active region between the gap regions. In the active region, the fingers 26b and the fingers 26d can overlap in the longitudinal direction. Similarly, the interdigital transducer electrode 30 can include a gap region between the fingers 30b and the bus bar 30c, a gap region between the fingers 30d and the first bus bar 30a, and an active region between the gap regions. In the active region, the fingers 30b and the fingers 30d can overlap in the longitudinal direction.

The first filter 10, the second filter 12, and the third filter 14 are closely positioned on a piezoelectric layer 16. The first filter 10 is spaced apart by a gap g1 from the second filter 12, and the second filter 12 is spaced apart by a gap g2 from the third filter 14. For example, the gaps g1, g2 can be in a range between 1 micrometer (μm) and 20 μm, 1 μm and 10 μm, 1 μm and 15 μm, 3 μm and 20 μm, 5 μm and 20 μm. Two or more of the first filter 10, the second filter 12, the third filter 14, and the terminals 21a, 21b, 21c can be connected through the conductive structure 20. The conductive structure 20 can include an electrical connection between two or more of the first filter 10, the second filter 12, the third filter 14, and the terminals 21a, 21b, 21c. In some embodiments, the conductive structure 20 can be an interconnect structure. The conductive structure 20 can include a first portion 20a that electrically connects to and extends between two or more of the first filter 10, the second filter 12, and the third filter 14. The conductive structure 20 can include a second portion 20b over at least a portion of the fingers 22b, 22d, 26b, 26d, 30b, 30d. There can be a gas gap 34 (e.g., an air gap) between the second portion 20b and the underlying fingers 22b, 22d, 26b, 26d, 30b, 30d. The second portion 20b can be referred to as a cantilever portion or an overhanging portion. The first portion 20a can be in electrical communication with (e.g., in direct or indirect contact with) the bus bar 22a, 22c, 26a, 26c, 30a, 30c and the second portion 20b can extend from the first portion 20a in a finger length direction of the fingers 22b, 22d, 26b, 26d, 30b, 30d to overlap at least a portion of the gap region, completely overlap the gap region, or overlap the gap region and at least a portion of the active region.

FIG. 3 is a schematic cross-sectional side view of the acoustic wave system 3. The acoustic wave system 3 is generally similar to the acoustic wave system 2 of FIGS. 2A and 2B. However, in the acoustic wave system 3, an electrical connection 36 that electrically connects the first filter 10, the second filter 12, and the third filter 14 overlaps and contacts the fingers of the interdigital transducer electrodes of the first filter 10, the second filter 12, and the third filter 14.

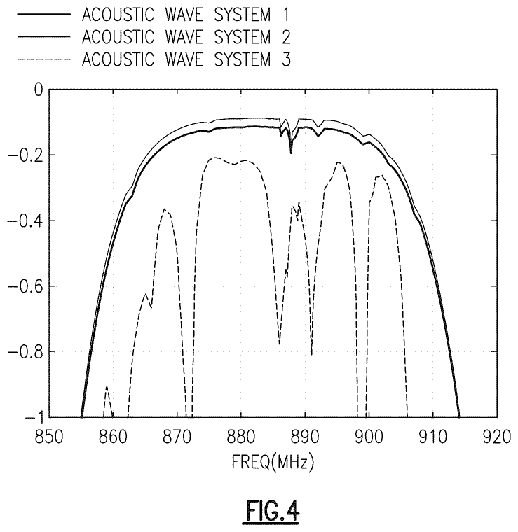

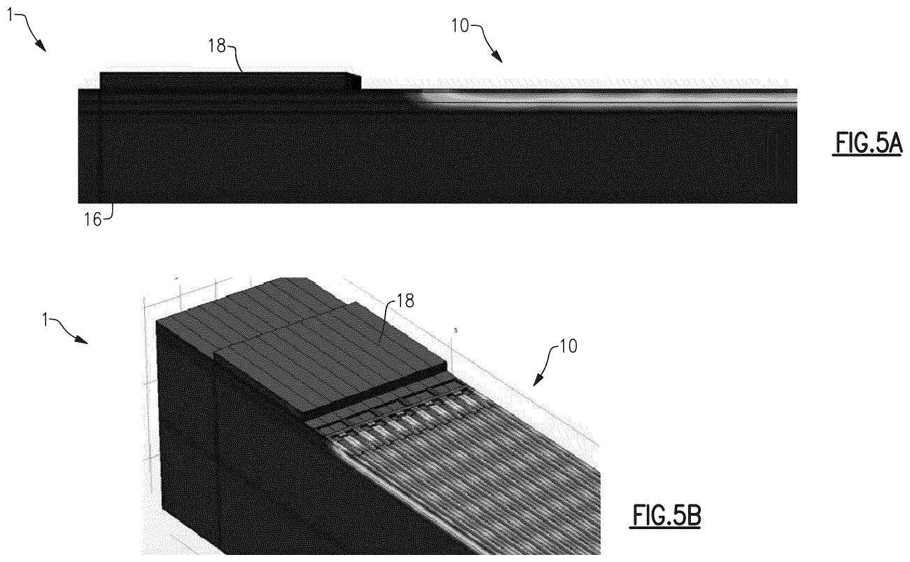

FIG. 4 is a graph of simulation results showing filter performance of the acoustic wave systems 1, 2, 3 shown in FIGS. 1A-3. The simulation results of FIG. 4 indicate that the conductive structure 20 that includes the first portion 20a and the second portion 20b can contribute to improving the performance (e.g., reduced insertion loss) of the acoustic wave system 2 compared to the acoustic wave systems 1, 3. Also, in the acoustic wave system 3 with the electrical connection 36 that overlaps and contacts the fingers, the performance significantly deteriorates. Accordingly, it would be undesirable to increase the widths of the electrical connection 18 of the acoustic wave system 1 beyond the gaps g1, g2 to have the electrical connection 36 of the acoustic wave system 3. In order to achieve the performance improvements by the conductive structure 20 demonstrated in FIG. 4, the gas gap (e.g., the air gap) between the second portion 20b of the conductive structure 20 can be significant. Further simulations were conducted to compare the performance of the acoustic wave systems 1, 2, 3 in FIGS. 5A-8C.

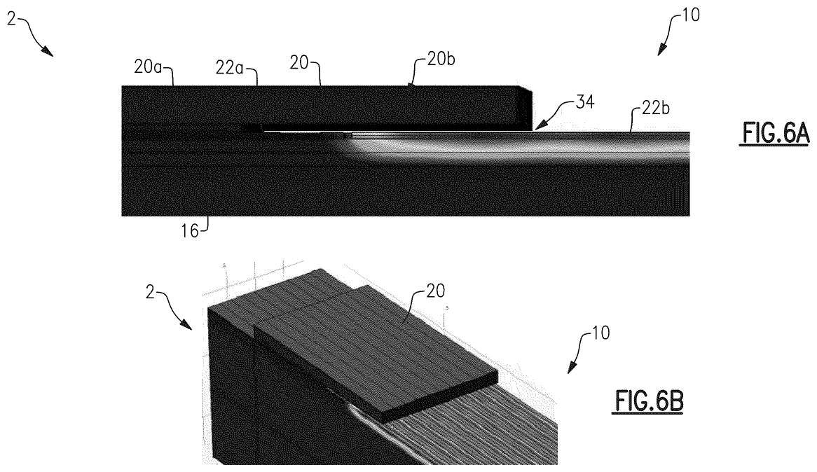

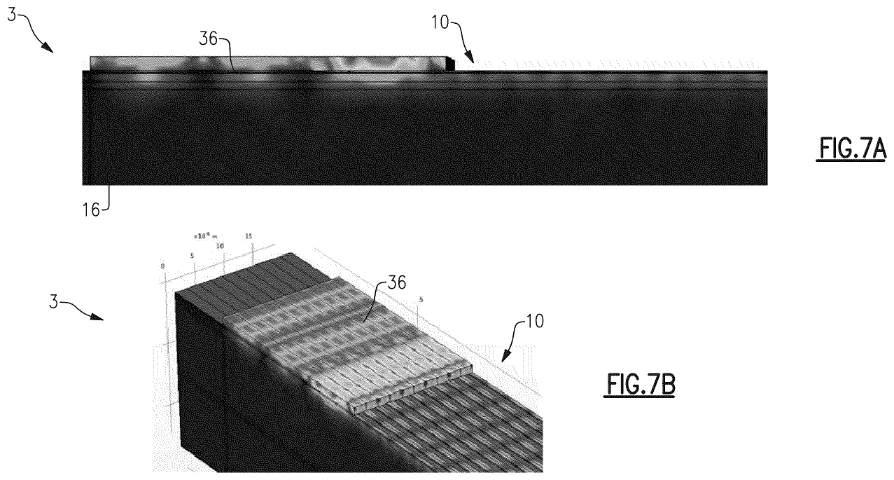

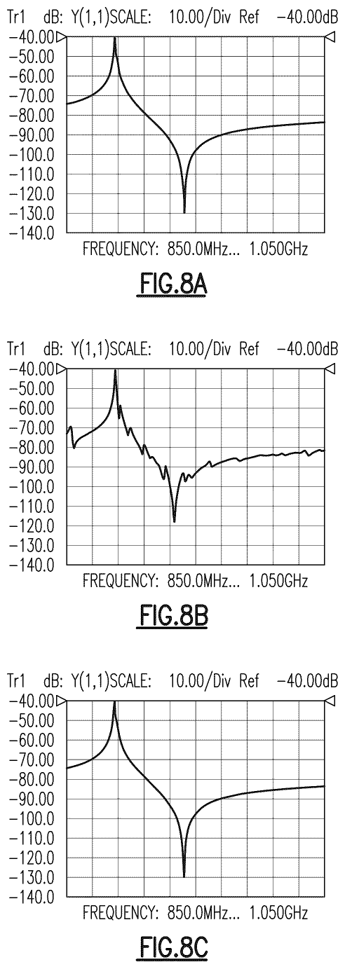

FIG. 5A is a schematic cross-sectional side view of a portion of the acoustic wave device 1 showing displacement in the acoustic wave device 1. FIG. 5B is a schematic perspective view of the acoustic wave device 1 showing displacement in the acoustic wave device 1. FIG. 6A is a schematic cross-sectional side view of a portion of the acoustic wave device 2 showing displacement in the acoustic wave device 2. FIG. 6B is a schematic perspective view of the acoustic wave device 2 showing displacement in the acoustic wave device 2. FIG. 7A is a schematic cross-sectional side view of a portion of the acoustic wave device 3 showing displacement in the acoustic wave device 3. FIG. 7B is a schematic perspective view of the acoustic wave device 3 showing displacement in the acoustic wave device 3. FIGS. 8A-8C are graphs showing simulated admittance of the acoustic wave systems 1, 2, 3.

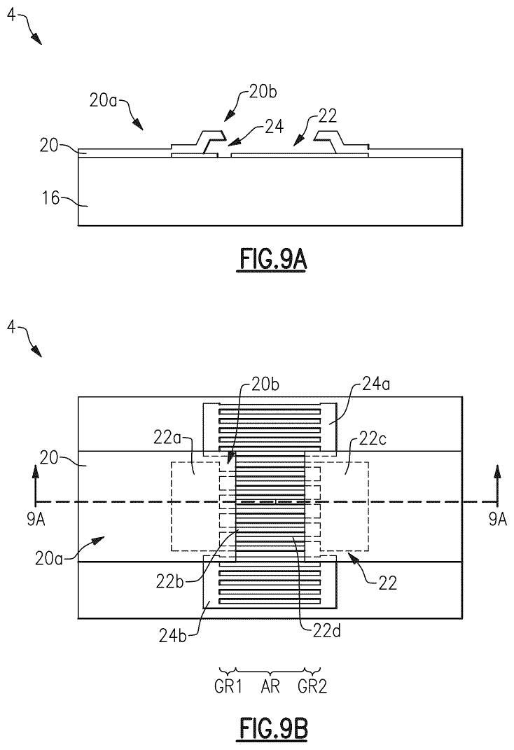

FIGS. 5A-7B indicate that the electrical connection 36 disturbs the resonance in the acoustic wave device 3. This results in the degradation of the frequency response of the acoustic wave system 3 as shown in FIG. 8B. Even with the second portion 20b of the conductive structure 20 that overlaps the fingers 22b of the interdigital transducer electrode 22, the acoustic wave system 2 can achieve a clean frequency response, as shown in FIG. 8C, due to the gas gap between the second portion 20b and the fingers 22b. Various features of the conductive structure 20 will be described in more detail in FIGS. 9A and 9B.

FIG. 9A is a schematic cross-sectional side view of an acoustic wave device 4 according to an embodiment. FIG. 9B is a schematic top plan view of the acoustic wave device 4. Unless otherwise noted, the components of the acoustic wave device 4 shown in FIGS. 9A and 9B may be structurally and/or functionally the same as or generally similar to like components disclosed herein. The acoustic wave device 4 can be a surface acoustic wave (SAW) device, such as a SAW ladder filter. In some embodiments, the acoustic wave device 4 can be included in an acoustic wave system (e.g., the acoustic wave system 2) as a filter (e.g., the first filter 10).

The acoustic wave device 4 can include an interdigital transducer electrode 22, a first reflector 24a, and a second reflector 24b positioned on a piezoelectric layer 16. The interdigital transducer electrode 22 can include a bus bar 22a, fingers 22b that extend from the bus bar 22a, a bus bar 22c, and fingers 22d that extend from the bus bar 22c. The interdigital transducer electrode 22 includes a first gap region GR1 between the bus bar 22a and the fingers 22d, a second gap region GR2 between the bus bar 22c and the fingers 22b, and an active region AR between the first and second gap regions GR1, GR2.

The acoustic wave device 4 can include a conductive structure 20 that includes a first portion 20a and a second portion 20b. The first portion 20a can be electrically connected to a terminal of the interdigital transducer electrode 22 which can be provided at a location of the bus bar 22a, 22c. The second potion 20b can overlap at least a portion of the fingers 22b, 22d. In some embodiments, the second portion 20b can be positioned at least partially over the gap region GR1, GR2, and/or the active region AR. For example, the second portion 20b can extend more than 1 μm, more than 5 μm, or more than 10 μm (e.g., in a range between 1 μm and 20 μm). In some embodiments, a thickness of the second portion 20b can be in a range between 0.1 μm and 5 μm, 0.5 μm and 5 μm, 1 μm and 5 μm, 0.5 μm and 3 μm, or 1 μm and 3 μm. The second portion 20b and the underlying fingers 22b, 22d are spaced apart by a gas gap 24 (e.g., an air gap). The gas gap 24 can mechanically isolate the second portion 20b from the underlying fingers 22b, 22d. In some embodiments, the second portion 20b can be widened in the longitudinal direction (e.g., the wave propagation direction) and at least partially overlap the reflector 24a, 24b.

The first portion 20a and the second portion 20b are in electrical communication with one another. The conductive structure 20 can include aluminum, copper, gold, or the like electrically conductive materials. In some embodiments, the first portion 20a and the second portion 20b can include different layers and/or different materials. The second portion 20b can be thicker than the first portion 20a, in some embodiments.

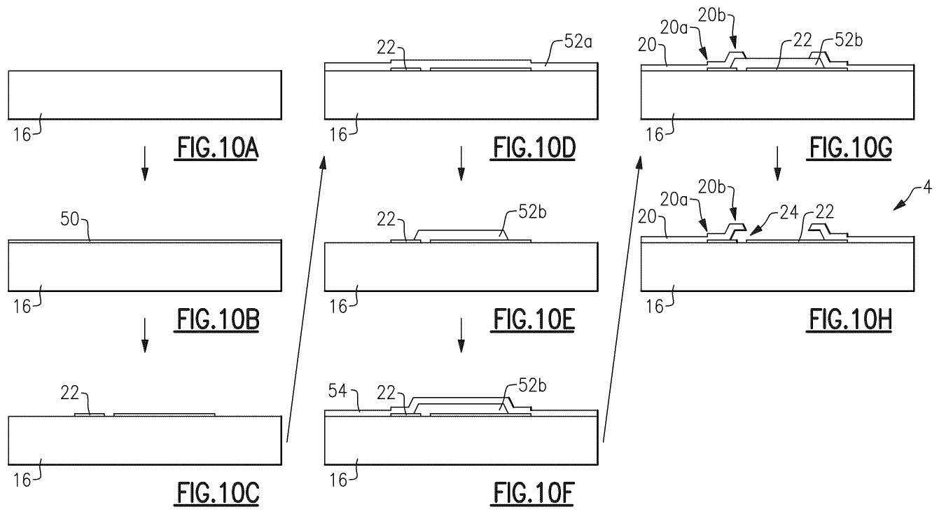

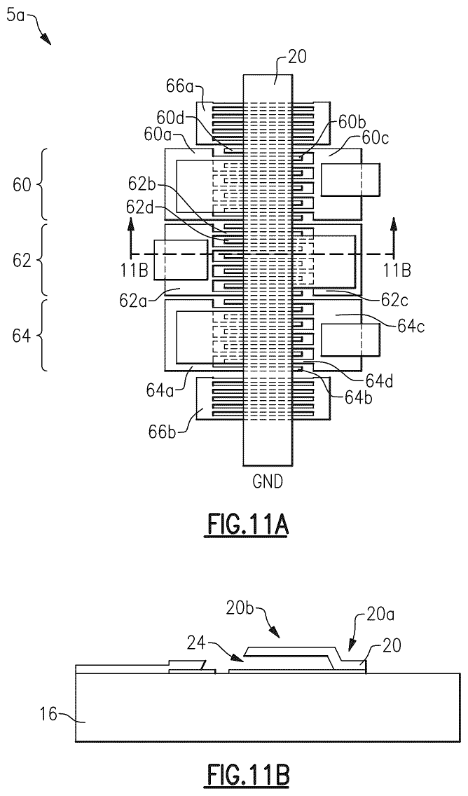

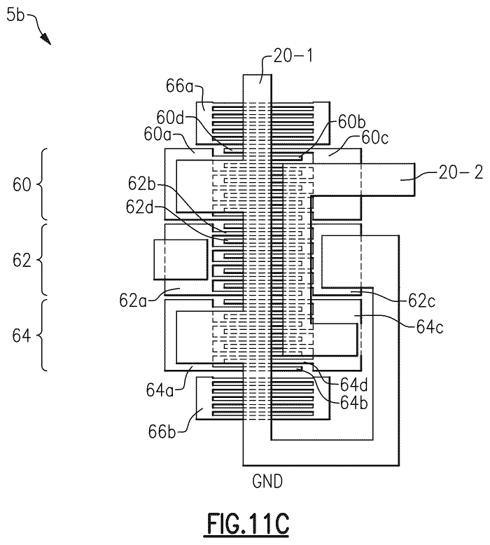

FIGS. 10A-10H show an example method of forming the acoustic wave device 4 according to an embodiment. In the description of the example method, reference may be made to the components shown in FIGS. 2A and 2B. Unless otherwise noted, the components of the acoustic wave device 4 shown in FIGS. 10A-10H may be structurally and/or functionally the same as or generally similar to like components disclosed herein. The acoustic wave device 4 can be part of an acoustic wave system (e.g., the acoustic wave system 2).

At FIG. 10A, a piezoelectric layer 16 can be provided. The piezoelectric layer 16 can include any suitable piezoelectric layer, such as a lithium based piezoelectric layer. In some embodiments, the piezoelectric layer 16 can be a lithium tantalate (LT) layer. For example, the piezoelectric layer 16 can be an LT layer having a cut angle of 20° (20° Y-cut X-propagation LT) or a cut angle of 60° (60° Y-cut X-propagation LT). For example, the piezoelectric layer 16 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 16. For example, the piezoelectric layer 16 can be an LN layer having a cut angle of about 118° (118° Y-cut X-propagation LN) or more or a cut angle of about 132° (132Y-cut X-propagation LN) or less. For example, the piezoelectric layer 16 can be 125±20° Y-cut LN, 125±15° Y-cut LN, 125±10° Y-cut LN, or 125±5° Y-cut LN. A thickness of the piezoelectric layer 16 can be selected based on a wavelength 2 or L of a surface acoustic wave generated by the SAW device 4 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 16 can be sufficiently thick to avoid significant frequency variation. For example, the thickness of the piezoelectric layer 16 can be in a range of 0.1 L to 0.5, 0.1 L to 0.3 L, or 0.1 L to 0.2 L. Selecting the thickness of the piezoelectric layer 16 from these ranges can be critical in avoiding significant frequency variation and providing sufficient temperature coefficient of frequency for the SAW device 4. In some embodiments, the piezoelectric layer 16 can include lithium tantalate (LT) and lithium niobate (LN).

At FIG. 10B, a conductive layer 50 suitable for forming an interdigital transducer electrode 22 can be provided. In some embodiments, the conductive layer 50 can have a multi-layer structure. The conductive layer 50 suitable for forming an interdigital transducer electrode 22 can include, for example, molybdenum (Mo), aluminum (Al), copper (Cu), Magnesium (Mg), titanium (Ti), tungsten (W), the like, or any suitable combination thereof. The conductive layer 50 may include alloys, such as AlMgCu, AlCu, etc.

At FIG. 10C, at least a portion of the conductive layer 50 can be removed (e.g., etched) to form the interdigital transducer electrode 22. Sequentially or in parallel, the reflectors 24a, 24b can also be formed. Although only one interdigital transducer electrode 22 is shown in the example method, a skilled artisan will understand that any suitable number of interdigital transducer electrodes can be formed on the same piezoelectric layer 16.

At FIG. 10D, a sacrificial layer 52a can be provided. For example, the sacrificial layer 52a can be deposited on the surfaces of the piezoelectric layer 16 and the interdigital transducer electrode 22.

At FIG. 10E, at least a portion of the sacrificial layer 52a can be removed to form the patterned sacrificial layer 52b. For example, the portion of the sacrificial layer 52a can be removed to form the patterned sacrificial layer 52b to expose at least a terminal for the interdigital transducer electrode 22. The terminal can be a portion of the bus bar 22a, 22c in some embodiments. The patterned sacrificial layer 52b can cover the fingers 22b, 22d of the interdigital transducer electrode 22.

At FIG. 10F, a conductive layer 54 can be provided (e.g., deposited) over surfaces of the piezoelectric layer 16, the interdigital transducer electrode 22, and the patterned sacrificial layer 52b. The conductive layer 54 can include aluminum, copper, gold, or the like electrically conductive materials. The conductive layer 54 can have a multi-layer structure, in some embodiments.

At FIG. 10G, at least a portion of the conductive layer 54 can be removed (e.g., etched) to define the conductive structure 20. The conductive structure 20 can include electrical connection between the interdigital transducer electrode 22 and a terminal of another interdigital transducer electrode (e.g., the interdigital transducer electrodes 26, 30 shown in FIG. 2A), and/or between the interdigital transducer electrode 22 and a terminal (e.g., the terminal 21a, 21b, 21c shown in FIG. 2A). The conductive structure 20 can include a first portion 20a and a second portion 20b. The first portion 20a can include the electrical connection. In some embodiments, the first portion 20a can be positioned at least partially over and in contact with the bus bar 22a, 22c of the inter digital transducer electrode 22. The second portion 20b can be positioned on the sacrificial layer 52b. The second portion 20b can at least partially overlap the fingers 22b, 22d.

At FIG. 10H, the sacrificial layer 52b can be removed. A gas gap 24 (e.g., an air gap) can be formed between the second portion 20b and the fingers 22b, 22d as a result of the removing process to remove the sacrificial layer 52b. The second portion 20b can extend from the first portion 20a in a finger length direction of the fingers 22b, 22d, 26b, 26d, 30b, 30d to overlap at least a portion of the gap region, completely overlap the gap region, or overlap the gap region and at least a portion of the active region. The second portion 20b can be referred to as a cantilever portion or an overhanging portion.

Any suitable principle and advantages disclosed herein related to the conductive structure 20 can be implemented in various acoustic wave devices or systems. For example, the conductive structure 20 disclosed herein can be implemented in a multi-mode surface acoustic wave device such as a double mode surface acoustic wave (DMS) device, a temperature compensated surface acoustic wave (TC-SAW) device, or a multi-layer piezoelectric substrate surface acoustic wave (MPS-SAW) device.

FIG. 11A is a schematic top plan view of a multi-mode surface acoustic wave device 5a according to an embodiment. FIG. 11B is a schematic cross-sectional side view of the multi-mode surface acoustic wave device 5a shown in FIG. 11A. Unless otherwise noted, the components of the acoustic wave device 5a shown in FIGS. 11A and 11B may be structurally and/or functionally the same as or generally similar to like components disclosed herein. The acoustic wave device 5a can be part of an acoustic wave system (e.g., the acoustic wave system 2).

The acoustic wave device 5a can include a first interdigital transducer electrode 60, a second interdigital transducer electrode 62, and a third interdigital transducer electrode 64 positioned longitudinally between a pair of reflectors 66a, 66b. Two or more of the first to third interdigital transducer electrode 60, 62, 64 can be electrically coupled through a conductive structure 20.

The first interdigital transducer electrode 60 includes a bus bar 60a, fingers 60b that extend from the bus bar 60a, a bus bar 60c, and fingers 60d that extend from the bus bar 60c. Similarly, the second interdigital transducer electrode 62 includes a bus bar 62a, fingers 62b that extend from the bus bar 62a, a bus bar 62c, and fingers 62d that extend from the bus bar 62c. The third interdigital transducer electrode 64 includes a bus bar 64a, fingers 64b that extend from the bus bar 64a, a bus bar 64c, and fingers 64d that extend from the bus bar 64c.

In the illustrated embodiment, the conductive structure 20 can electrically couple the busbar 60a of the interdigital transducer electrode 60, the bus bar 62c of the interdigital transducer electrode 62, and the bus bar 64a of the interdigital transducer electrode 64 to provide ground (GND) connection. In some embodiments, the conductive structure 20 can include an electrical routing structure. The conductive structure 20 can include a first portion 20a that is electrically connected to a terminal of the bus bar 60a, 62c, 64a, and a second portion 20b that is positioned at least partially over the fingers 60b, 60d, 62b, 62d, 64b, 64d. The second portion 20b is spaced apart from the underlying fingers 60b, 60d, 62b, 62d, 64b, 64d by a gas gap 24 (e.g., air gap). The conductive structure 20 can provide electrical connections between other parts of the acoustic wave device 5a.

FIG. 11C is a schematic top plan view of a multi-mode surface acoustic wave device 5b according to an embodiment. Unless otherwise noted, the components of the acoustic wave device 5b shown in FIG. 11C may be structurally and/or functionally the same as or generally similar to like components disclosed herein. The acoustic wave device 5b can be generally similar to the acoustic wave device 5a of FIG. 11A. The acoustic wave device 5b can include a first conductive structure 20-1 and a second conductive structure 20-2. The first conductive structure 20-1 and the second conductive structure 20-2 can provide separate electrical connections between components of the acoustic wave device 5b. For example, the first conductive structure 20-1 can provide a ground (GND) connection, and the second conductive structure 20-2 can provide a signal connection.

In various applications, the conductive structures disclosed herein can provide design flexibility, which allows the lateral size of an acoustic wave system to be reduced while improving the performance of the acoustic wave system.

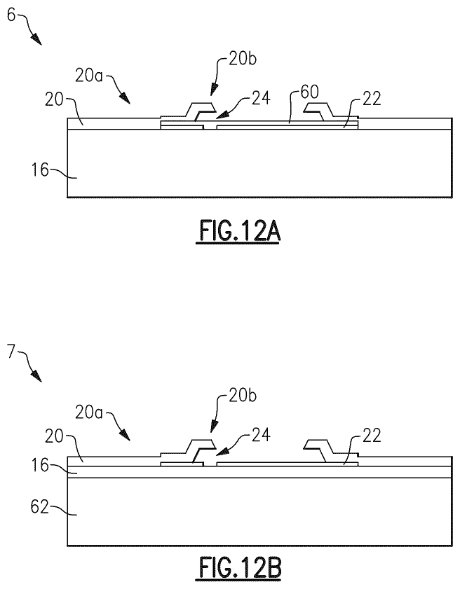

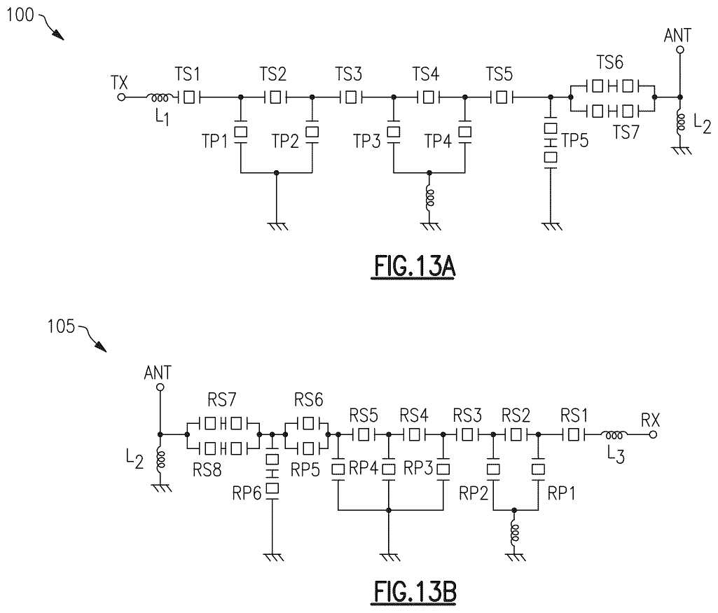

FIG. 12A is a schematic cross-sectional side view of an acoustic wave device 6 according to an embodiment. FIG. 12B is a schematic cross-sectional side view of an acoustic wave device 7 according to an embodiment. Unless otherwise noted, the components of the acoustic wave devices 6, 7 shown in FIGS. 12A and 12B may be structurally and/or functionally the same as or generally similar to like components disclosed herein. The acoustic wave device 6 can be an example of a temperature compensated surface acoustic wave (TC-SAW) device, and the acoustic wave device 7 can be an example of a multi-layer piezoelectric substrate surface acoustic wave (MPS-SAW) device.

The acoustic wave device 6 can include a layer 60 over the interdigital transducer electrode 22. In some embodiments, the layer 60 can include a temperature compensation layer. The temperature compensation layer (e.g., a silicon dioxide layer) can bring a temperature coefficient of frequency closer to zero. In some other embodiments, the layer 60 can include a passivation layer or a frequency trimming layer. The second portion 20b of the conductive structure 20 is spaced apart from the underlying layer 60 by a gas gap 24.

The acoustic wave device 7 can include a support substrate 62. The support substrate 62 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, an aluminum oxide layer, or the like. The support substrate 62 can have a relatively high acoustic impedance. For example, the support substrate 62 can have a higher impedance than an impedance of the piezoelectric layer 16 and a higher thermal conductivity than a thermal conductivity of the piezoelectric layer 16. In some embodiments, there can be a trap rich layer that may be formed between the support substrate 62 and the piezoelectric layer 16.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 13A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 13B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 13A and 13B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

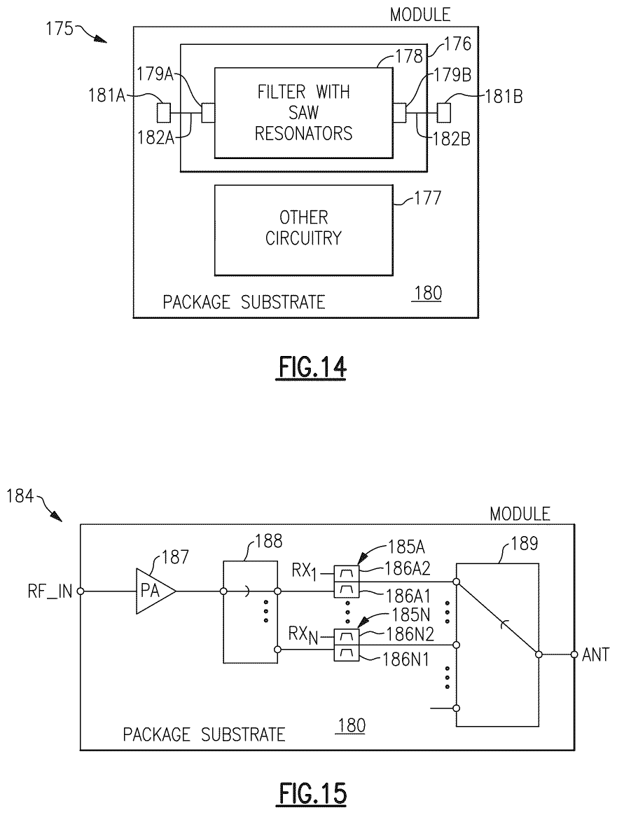

FIG. 14 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 14 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 14. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 15 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

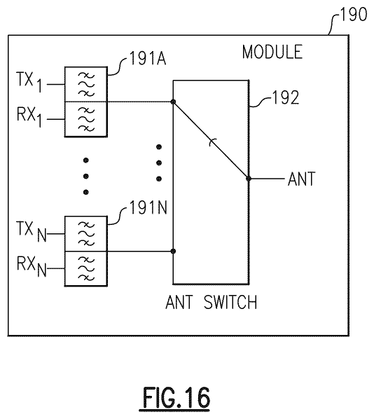

FIG. 16 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

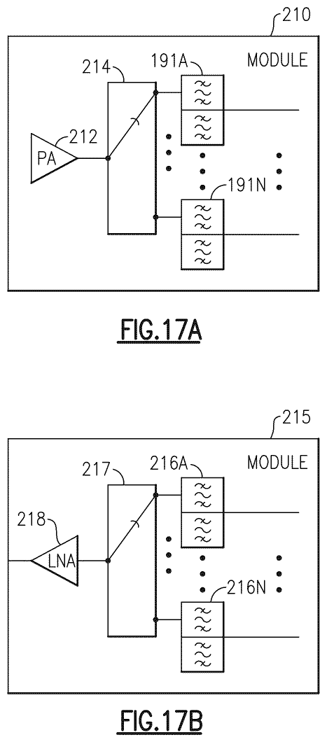

FIG. 17A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 17B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

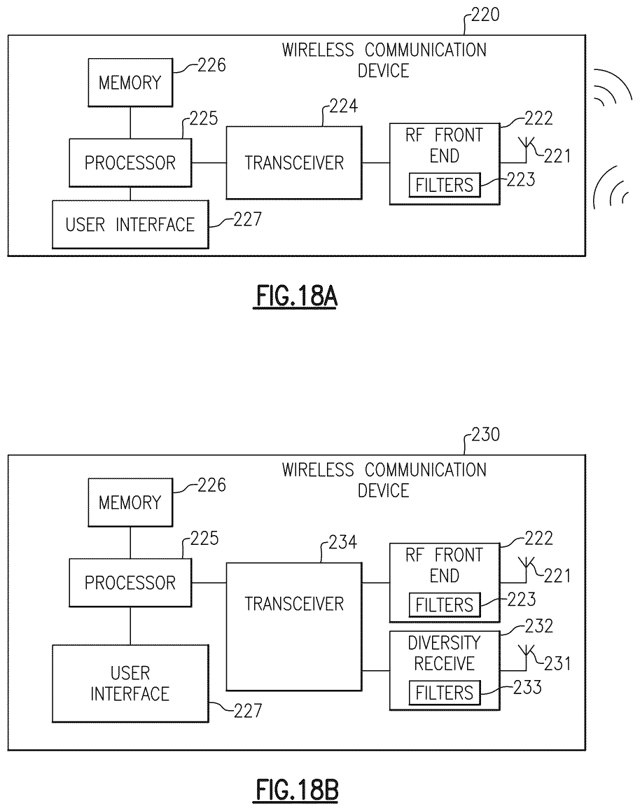

FIG. 18A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 18B is a schematic diagram of a wireless communication device 230 that includes filters 223 in a radio frequency front end 222 and a second filter 233 in a diversity receive module 232. The wireless communication device 230 is like the wireless communication device 220 of FIG. 18A, except that the wireless communication device 230 also includes diversity receive features. As illustrated in FIG. 18B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a piezoelectric layer;
an interdigital transducer electrode over the piezoelectric layer, the interdigital transducer electrode including a first bus bar, a first set of fingers extending from the first bus bar, a second bus bar, and a second set of fingers extending from the second bus bar; and
a conductive structure including a first portion positioned on the first bus bar and a second portion at least partially positioned over the first set of finger fingers, the second portion spaced from the first set of fingers by a gap.

2. The acoustic wave device of claim 1 wherein the gap is an air gap.

3. The acoustic wave device of claim 2 further comprising a temperature compensation layer between the air gap and the interdigital transducer electrode.

4. The acoustic wave device of claim 1 wherein the interdigital transducer electrode includes a first gap region between the first bus bar and the second set of fingers, a second gap region between the second bus bar and the first set of fingers, and an active region between the first and second gap regions, the second portion is at least partially positioned over the first gap region.

5. The acoustic wave device of claim 4 wherein the second portion is at least partially positioned over the active region.

6. The acoustic wave device of claim 4 further comprising a second conductive structure, wherein the second conductive structure includes a third portion positioned on the second bus bar and a fourth portion at least partially positioned over the second gap region, the second portion is spaced from the second set of fingers.

7. The acoustic wave device of claim 6 wherein the fourth portion is at least partially positioned over the active region.

8. The acoustic wave device of claim 1 further comprising a first reflector and a second reflector, the interdigital transducer electrode positioned between the first and second reflectors.

9. The acoustic wave device of claim 8 wherein the second portion is at least partially positioned over the first reflector.

10. The acoustic wave device of claim 1 wherein the piezoelectric layer includes lithium niobate or lithium tantalate.

11. The acoustic wave device of claim 10 further including a support substrate, the piezoelectric layer is positioned between the support substrate and the interdigital transducer electrode.

12. An acoustic wave device comprising:
a piezoelectric layer;
an interdigital transducer electrode over the piezoelectric layer, the interdigital transducer electrode including a first gap region, a second gap region, and an active region laterally between the first and second gap regions; and
a conductive structure electrically connected to the interdigital transducer electrode, a portion of the conductive structure positioned over the first gap region, the portion of the conductive structure spaced from the first gap region by an air gap.

13. The acoustic wave device of claim 12 wherein the portion of the conductive structure is positioned over the active region.

14. The acoustic wave device of claim 12 further comprising a second conductive structure, wherein the second conductive structure is at least partially positioned over the active region.

15. The acoustic wave device of claim 12 wherein the conductive structure includes a first metal layer and a second metal layer over the first metal layer.

16. The acoustic wave device of claim 15 wherein the first metal layer and the second metal layer include different materials.

17. The acoustic wave device of claim 15 wherein the second metal layer is thicker than the first metal layer.

18. An acoustic wave system comprising the acoustic wave device of claim 12 and another acoustic wave device.

19. A surface acoustic wave device comprising:
a piezoelectric layer;
an interdigital transducer electrode over the piezoelectric layer; and
a conductive structure electrically connected to a terminal of the interdigital transducer electrode and partially positioned over an active region of the interdigital transducer electrode, the conductive structure spaced from the interdigital transducer electrode by an air gap.

20. An acoustic wave system comprising the acoustic wave device of claim 19 and a second acoustic wave device spaced from the acoustic wave device by a distance in a range between 1 micrometer and 20 micrometers.
